(19) United States
(12) Patent Application Publication
(10) Pub. No.: US 2023/0029761 A1
(43) Pub. Date: Feb. 2, 2023

(54) Run-time reconfigurable accelerator for matrix multiplication

(71) Applicant: PES University, Bangalore (IN)

(72) Inventors: Madhura Purnaprajna, Bangalore (IN); Ashuthosh Moolemajalu Ravikumar, Madikeri (IN); Santosh Krishna, Bangalore (IN)

(73) Assignee: PES UNIVERSITY, Bangalore (IN)

(21) Appl. No.: 17/552,289

(22) Filed: Dec. 15, 2021

(30) Foreign Application Priority Data
Jul. 27, 2021 (IN) 202141033604

(51) Int. Cl. G06F 30/343; G06F 30/347; G06F 30/3323; G06F 17/16

(52) U.S. Cl. CPC G06F 30/343; G06F 30/347; G06F 30/3323; G06F 17/16

(57) ABSTRACT

Matrix multipliers are computationally complex, and memory intensive algorithms used frequently in a variety of applications, such as deep-learning and scientific computations. Accelerating matrix multiplication involves an inter-play of algorithm-architecture co-design and context-specific design parameters. A performance optimizer intelligently arrives at the right combination of algorithm (203)-architecture specifications (201, 202) for the input design parameters that arrive during real-time for a target-specific design constraint. The run-time customization leads to optimal power-performance-area optimization.

### BACKGROUND

This invention relates to developing a run time optimized hardware accelerator.

There is a long felt but unresolved need for developing a performance model that finds the right match between algorithm and system resources.

### SUMMARY OF THE INVENTION

Matrix multipliers are computationally complex and memory intensive algorithm used frequently in a variety of applications, such as deep-learning and scientific computations. Accelerating matrix multiplication involves an inter-play of algorithm-architecture co-design and context-specific design parameters. A performance optimizer intelligently arrives at the right combination of algorithm-architecture specifications for the input design parameters that arrive during real-time for a target-specific design constraint. The run-time customization leads to optimal power-performance-area optimization.

It is an aspect of the invention to provide user transparent performance tuning, through run-time reconfiguration.

It is an aspect of the invention to provide context-specific optimization, to match application specifications to target constraints

It is another aspect of the invention to provide a high accuracy of performance prediction.

It is a further aspect of the invention to provide the flexibility to be upgraded with newer algorithms, matrix computations and state-of-the-art devices.

### BRIEF DESCRIPTION OF THE DRAWINGS

FIG. 1 illustrates the method of identifying a match between matrix parameters and device specific resource constraints to arrive at the right choice of algorithm to meet user-specific performance requirements.

FIG. 2 illustrates a performance optimizer, named MATAnalyse to match variations in matrix parameters and device-specific resource constraints.

FIG. 3 illustrates a snippet of the Verilog implementation

FIG. 4 exemplarily displays the set of results obtained for three cases with variation of input parameters.

FIG. 5 illustrates the performance estimation methodology used by the performance optimizer.

FIG. 6 exemplarily illustrates a use case of implementation obtained through MATAnalyse.

### DETAILED DESCRIPTION

In the following description, for purposes of explanation, numerous specific details are set forth in order to provide a thorough understanding of the invention. It will be apparent, however, to one skilled in the art that the invention may be practiced without these specific details. In other instances, structures and devices are shown in block diagram form only in order to avoid obscuring the invention.

Moreover, although the following description contains many specifics for the purposes of illustration, anyone skilled in the art will appreciate that many variations and/or alterations to said details are within the scope of the present invention. Similarly, although many of the features of the present invention are described in terms of each other, or in conjunction with each other, one skilled in the art will appreciate that many of these features can be provided independently of other features. Accordingly, this description of the invention is set forth without any loss of generality to, and without imposing limitations upon, the invention.

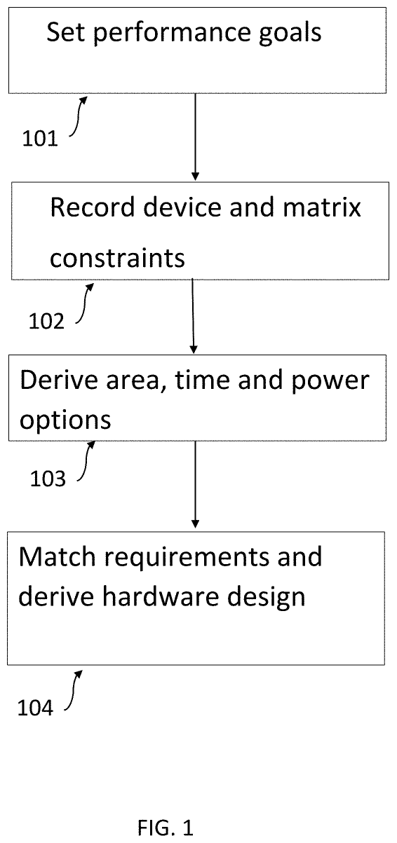

FIG. 1 illustrates the method of identifying a match between matrix parameters and device specific resource constraints to arrive at the right choice of algorithm to meet user-specific performance requirements. The user sets performance goals 101. The performance goal is the priority setting among the parameters of time, power and area. Record the matrix's constraints 102 comprising dimensions, sparsity and available algorithms for the user-defined specifications of the input matrix. Record the device's constraints comprising memory and computation resources. Derive area options 103 to meet each and a combination of the matrix and device constraints, derive time periods for computation for each of the area options and derive power requirements for each of the derived time periods. Arrive at the right choice of algorithm and select a hardware design by matching 104 the performance goals of the user with the above derived area options, derived time periods and derived power requirements.

The performance optimizer, named MATAnalyse 206 hereafter, works on design constraints and performance metrics for the user-defined context. For a given application scenario, when the input matrix specifications and performance goals are set, MATAnalyse 206 arrives at the right match of design constraints and performance goals at run-time. The footprint of MATAnalyse 206 is small and can be accommodated on an on-chip soft processor. The run-time of MATAnalyse 206 compensates for the run-time performance advantage of customization.

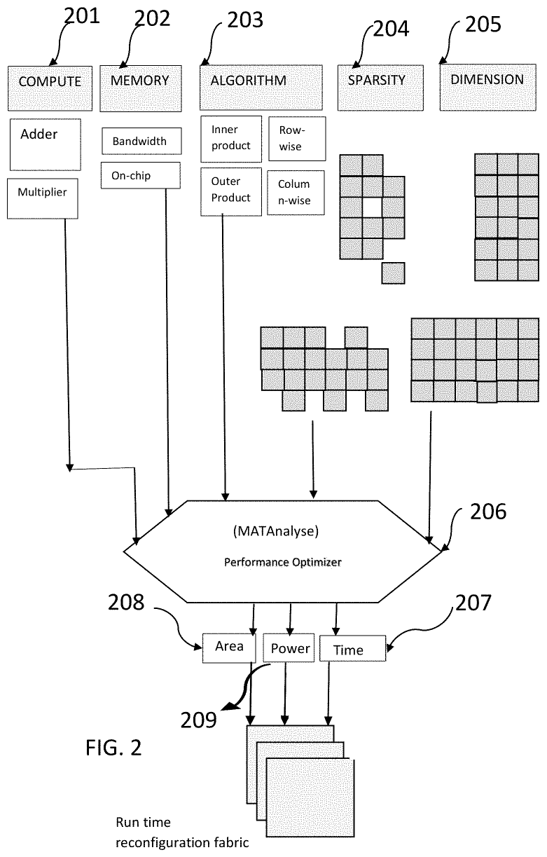

FIG. 2 illustrates a performance optimizer, named MATAnalyse 206 to match variations in matrix parameters and device-specific resource constraints.

Described herein is a hardware accelerator for matrix multiplication that can be configured to operate with sparse and dense matrices. The performance of the accelerator is dependent on several key factors based on the hardware implementation. Described below is a list of the different parameters that make an impact on the overall performance in terms of time, power and area.

1. Location, sparsity 204 and data-type of the input matrices

2. Compression technique for the given sparsity

3. Algorithms 203 for matrix multiplication

4. Memory 202 constraint on the target device

5. Compute 201 composition of the target device

In order to assess the performance quality of a generic matrix multiplier, the following performance metrics (time, energy and power, area) are used to identify the most suitable design based on the given input specifications. A brief description of the different performance parameters and how they are evaluated for different design choices is described hereafter.

Time (Latency) 207: The total latency 207 is a function of the number of processing compute elements and the available off-chip to on-chip memory bandwidth of the target device. The number of processing compute elements decides the maximum number of computations that can be accomplished in one cycle.

The memory bandwidth available may be used to classify the design majorly into two distinct designs, compute bound and memory bound design. A design is said to be compute bound if the data coming in through the interface in one cycle cannot all be processed by the available on-chip resources in the same cycle. Similarly, the design is said to be memory bound if the data arriving every cycle through the interface is insufficient to use 100% of the on-chip compute resources.

In the compute bound case, there is enough or more than enough data available to feed data to all the compute elements. In the memory bound case, the utilization of processing compute elements will remain below 100% since the data to the processing compute elements is limited by the memory bandwidth. The total latency in this case is a function of the number of computations and the number of compute elements available. With the additional information of the critical path in the design, the operating frequency and consequently the total execution time can be estimated.

Energy and Power 209: The energy required is dependent on the number of memory accesses and the number of computations. The number of memory accesses required varies with the compression format under consideration while the total number of multiplications that needs to be done remains constant across different algorithms and compression formats. The impact of compression formats can be seen as the number of computations to compress/decompress data changes with the chosen compression format.

Therefore, the total number of computations constitutes the number of multiplications and the required compression/decompression of the data. With the knowledge of the energy required for memory accesses, computations and also the total execution time, the total power requirements of the system can be estimated.

Area 208: The total area of the design can be categorized as the compute area and memory footprint. The compute area is directly related to the number of computational resources required, which is algorithm-dependent.

For the memory footprint, based on the percentage sparsity and dimensions 205 of the input matrices, the number of non-zeros (NNZ) in the matrix can be calculated. Based on the NNZ, the total storage required for storing the entire matrix is estimated for a given compression format.

The other requirement of memory footprint stems from the partial products that are generated during the process of computing the resultant matrix. The number of partial products generated are entirely algorithm-dependent. With the knowledge of algorithm and compression format, the required on-chip area is estimated.

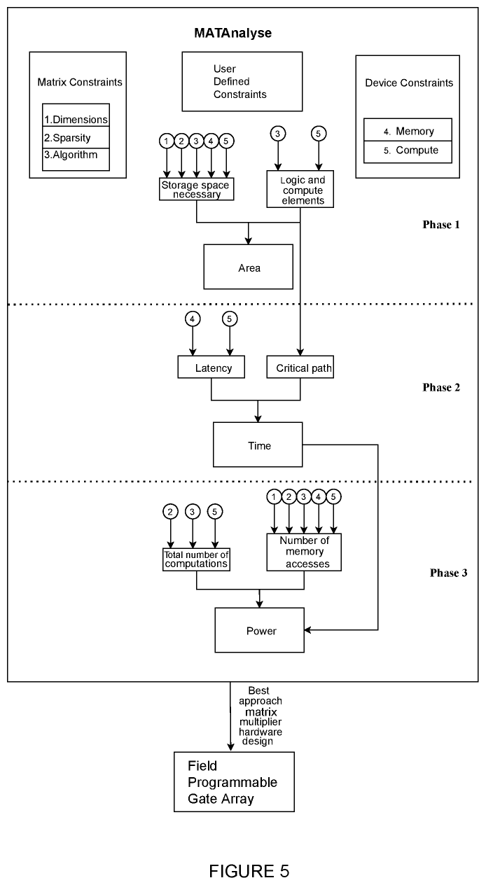

FIG. 5 illustrates the performance estimation methodology used by the performance optimizer. It depicts the dependencies and steps to be followed while deriving the performance parameters in terms of area, time and power. The methodology is divided into three phases, where each phase is dependent on the results obtained in the preceding phases. The dependencies between the blocks are connected with arrows in the diagram. The numbers over certain blocks shows the dependency of block on respective input parameters. The final design is found based on the constraints such as low power, low area or high performance defined by the user. Finally, depending on the device constraints, the hardware design is programmed on the FPGA device.

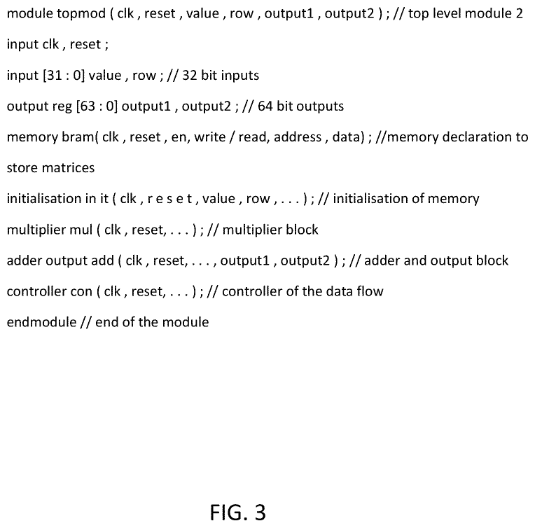

FIG. 3 illustrates a snippet of the Verilog implementation.

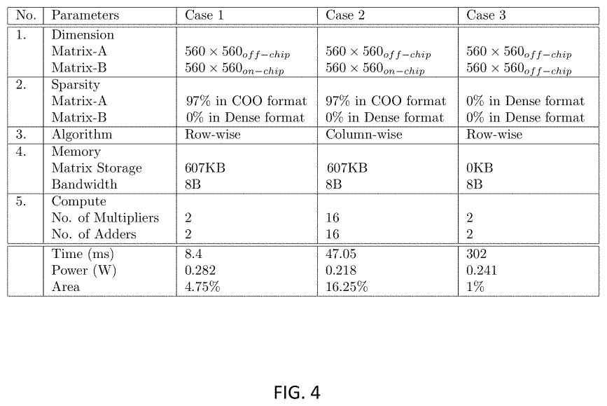

FIG. 4 exemplarily displays the set of results obtained for three cases with variation of input parameters. The FPGA device considered is Xilinx Artix XC7A100TCSG324-1. The input parameters for each case in the following denote:

Dimension 205: The dimension 205 of the two input matrices.

The location of the matrices can either be on-chip or off-chip, and the table depicts the cases considered.

Sparsity 204: The sparsity of the two matrices and the corresponding format decided based on the sparsity 204 for the matrix is mentioned.

Algorithm: The algorithm of the matrix multiplication implemented.

Memory: The memory parameter involves the storage space for the matrices and the bandwidth which indicates the amount of data obtained every clock cycle from the off-chip memory.

Compute 201: The compute elements include the number of multipliers and adders utilized by the matrix multi-plier. From the three cases, it is observed that the variation in one or more parameters result in deviation of the performance in terms of time, power and area.

Case 1 is the best among the three cases in terms of speed (time). Hence, Case 1 is preferred if the user sets speedup to be the goal over power and area. Similarly Case 2 is preferred for low power applications and Case 3 is recommended for the applications with less area.

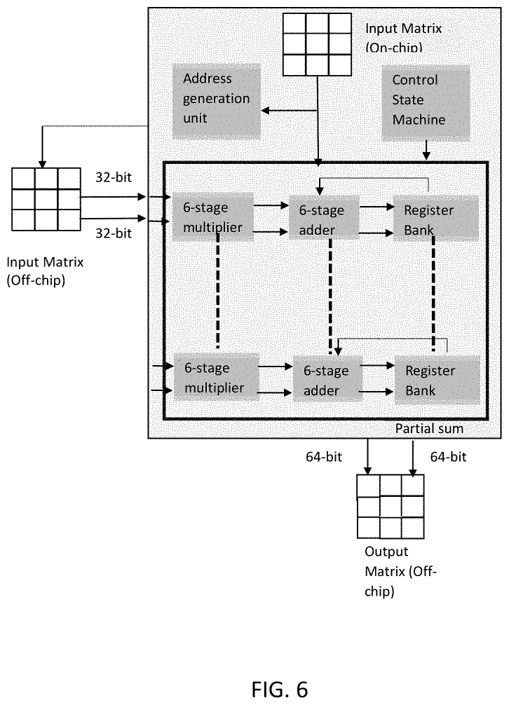

FIG. 6 exemplarily illustrates a use case of implementation through MATAnalyse. This hardware implementation was used to validate the results of MATAnalyse 206. The internals of the modules titled matrix, multiplier and adder-output contain the functional description which is based on the algorithm and other input parameters. FIG. 6 depicts an address generation unit, control state machine and utilizes a 6 stage pipeline for both adders and multipliers.

The processing steps described above may be implemented as modules. As used herein, the term “module” might describe a given unit of functionality that can be performed in accordance with one or more embodiments of the present invention. As used herein, a module might be implemented utilizing any form of hardware, such as ASICs or FPGAs to make up a module. In implementation, the various modules described herein might be implemented as discrete modules or the functions and features described can be shared in part or in total among one or more modules.

The foregoing examples have been provided merely for explanation and are in no way to be construed as limiting performance optimizer disclosed herein. While performance optimizer has been described with reference to various embodiments, it is understood that the words, which have been used herein, are words of description and illustration, rather than words of limitation. Furthermore, although the performance optimizer has been described herein with reference to particular means, materials, and embodiments, the performance optimizer is not intended to be limited to the particulars disclosed herein; rather, the performance optimizer extends to all functionally equivalent structures, methods and uses, such as are within the scope of the appended claims. While multiple embodiments are disclosed, it will be understood by those skilled in the art, having the benefit of the teachings of this specification, that the performance optimizer disclosed herein are capable of modifications and other embodiments may be effected and changes may be made thereto, without departing from the scope and spirit of the performance optimizer disclosed herein.

We claim:

1. A computer-implemented method to implement a hardware accelerator for matrix multiplication on a device, to meet user specific performance requirements, comprising:
setting performance goals by said user, wherein said performance goal is user-specific input/output matrix constraints of a combination of time, power, and area;
recording said matrix's constraints comprising dimensions, sparsity, and available algorithms;
recording said device's constraints comprising memory and computation resources;
deriving said area options to meet each and a combination of said matrix and device constraints;
deriving said time periods for computation for each of said area options;
deriving said power requirements for each of said derived time periods; and
arriving at said right choice of algorithm and selecting a hardware design by matching said performance goals of the user with said derived area options, said derived time periods and said derived power requirements.

2. The computer-implemented method of claim 1, wherein said step of deriving the area requirements comprises of determining storage space and computational resources.

3. The computer implemented method of claim 2, wherein said storage space is a function of the parameters of matrix dimensions, matrix sparsity, algorithm, memory resources and computation resources.

4. The computer implemented method of claim 1, wherein said time consumed is a function of latency and critical path.

5. The computer implemented method of claim 4, wherein said latency is a function of memory and compute resources.

6. The computer implemented method of claim 4, wherein total of said latency is a function of the number of processing compute elements and the available off-chip to on-chip memory bandwidth of a target device, and the number of processing compute elements which decides the maximum number of computations that can be accomplished in one cycle.

7. The computer implemented method of claim 1, wherein said selected hardware design is programmed on a FPGA device.

8. The computer implemented method of claim 1, wherein said selection of hardware design is transparent to said user through run time reconfiguration.

9. The computer implemented method of claim 1, wherein total of said area of the design can be categorized as compute area and memory footprint, and said compute area is directly related to the number of computational resources required; and said memory footprint is based on the percentage sparsity and dimensions of the input matrices, and the number of non-zeros (NNZ) in the matrix.

10. The method of claim 9, wherein the total storage required for storing the entire matrix is estimated for the most appropriate compression format utilizing information on said number of non-zeros (NNZ).

11. The computer implemented method of claim 1, wherein said power required is dependent on the number of memory accesses and the number of computations, and said number of memory accesses required varies with the compression format under consideration, while the total number of multiplications that needs to be done remains constant across different algorithms and compression formats, and wherein the total number of computations involves compressing and decompressing of data based on the compression format.

12. A system for identifying a match between matrix parameters and device specific resource constraints to arrive at the right choice of algorithm to meet user-specific performance requirements, comprising;
at least one processor;
a non-transitory computer readable storage medium communicatively coupled to said at least one processor, said non-transitory computer readable storage medium configured to store modules, said at least one processor configured to execute said modules; and
said modules comprising:
a first module for setting performance goals by said user, wherein said performance goal comprise the parameters of time, power and area;
a second module for recording said matrices' constraints of dimensions, sparsity and algorithm and for recording said device's constraints of memory and computation resources;
a third module for,
deriving said area options to meet each and a combination of said matrix and device constraints;
deriving said time periods for computation for each of said area options;
deriving said power requirements for each of said derived time periods; and
a fourth module for selecting a hardware design by matching said performance goals of the user with said derived area options, said derived time periods and said derived power requirements.
